(19) United States
(12) Patent Application Publication
(10) Pub. No.: US 2026/0090240 A1
(43) Pub. Date: Mar. 26, 2026

(54) DISPLAY PANEL AND MANUFACTURING METHOD THEREFOR, AND DISPLAY APPARATUS

(71) Applicant: Shanghai Tianma Microelectronics Co, Ltd., Shanghai (CN)

(72) Inventors: Qian GU, Shanghai (CN); Xingbang ZHOU, Shanghai (CN); Xiaoni CHEN, Shanghai (CN); Weiwei YANG, Shanghai (CN)

(73) Assignee: Shanghai Tianma Microelectronics Co, Ltd., Shanghai (CN)

(21) Appl. No.: 19/001,443

(22) Filed: Dec. 25, 2024

(30) Foreign Application Priority Data
Sep. 20, 2024 (CN) 202411320259.4

(51) Int. Cl. H10K 59/80

(52) U.S. Cl. CPC H10K 59/873; H10K 59/879

(57) ABSTRACT

The present application relates to a display panel and a manufacturing method therefor, and a display apparatus. The display panel comprises: a substrate; at least one inorganic encapsulation layer made of an inorganic material and disposed on one side of the substrate; and at least one repair encapsulation layer disposed on the side of the at least one inorganic encapsulation layer away from the substrate, the repair encapsulation layer being in contact with the inorganic encapsulation layer adjacently disposed on a side of the repair encapsulation layer close to the substrate, and materials of the repair encapsulation layer including an inorganic material and an organic material. The present application can improve the reliability of the display panel.

### CROSS REFERENCE TO RELATED APPLICATION

The present application claims priority to Chinese Patent Application No. 202411320259.4 filed on Sep. 20, 2024, which is incorporated herein by reference in its entirety.

### TECHNICAL FIELD

The present application relates to the field of display technology, in particular to a display panel and a manufacturing method therefor, and a display apparatus.

### BACKGROUND

With the continuous development of display technology, organic light-emitting diode (OLED) display apparatuses have been widely used in various fields such as flat panel displays, flexible displays, vehicle displays, and solid-state lighting due to their advantages of wide color gamut, high contrast, energy saving, and foldability.

### SUMMARY

In a first aspect, embodiments of the present application provide a display panel, including:
a substrate;
at least one inorganic encapsulation layer, made of an inorganic material and disposed on one side of the substrate; and
at least one repair encapsulation layer, disposed on the side of the at least one inorganic encapsulation layer away from the substrate, and the repair encapsulation layer being in contact with the inorganic encapsulation layer adjacently disposed on a side of the repair encapsulation layer close to the substrate, where the repair encapsulation layer include an inorganic material and an organic material.

In a second aspect, embodiments of the present application further provide a manufacturing method for a display panel, including:
providing a substrate;
forming at least one inorganic encapsulation layer on one side of the substrate by a vapor deposition process, the inorganic encapsulation layer being made of an inorganic material; and
forming at least one repair encapsulation layer on the side of the at least one inorganic encapsulation layer away from the substrate by a solution method, the repair encapsulation layer being in contact with the inorganic encapsulation layer adjacently disposed on a side of the repair encapsulation layer close to the substrate, and the repair encapsulation layer including an inorganic material and an organic material.

In a third aspect, embodiments of the present application further provide a display apparatus, including the display panel provided in the first aspect.

### BRIEF DESCRIPTION OF THE DRAWINGS

In order to provide a clearer explanation of the technical solutions in embodiments of the present application or conventional technologies, the accompanying drawings required for use in the description of embodiments or the conventional technologies will be simply introduced below. Apparently, the accompanying drawings in the following description show only some embodiments of the present application. Those of ordinary skill in the art can derive other drawings according to these accompanying drawings without any creative efforts.

FIG. 1 is a schematic view of a first cross-sectional structure of a display panel provided in some embodiments of the present application;

FIG. 2 is a schematic view of a second cross-sectional structure of a display panel provided in some embodiments of the present application;

FIG. 3 is a schematic view of a third cross-sectional structure of a display panel provided in some embodiments of the present application;

FIG. 4 is a schematic view of a fourth cross-sectional structure of a display panel provided in some embodiments of the present application;

FIG. 5 is a schematic view of a fifth cross-sectional structure of a display panel provided in some embodiments of the present application;

FIG. 6 is a schematic view of a sixth cross-sectional structure of a display panel provided in some embodiments of the present application;

FIG. 7 is a schematic view of first process steps of a manufacturing method for a display panel provided in some embodiments of the present application;

FIG. 8 is a schematic view of second process steps of a manufacturing method for a display panel provided in some embodiments of the present application;

FIG. 9 is a schematic view of third process steps of a manufacturing method for a display panel provided in some embodiments of the present application;

FIG. 10 is a schematic view of a first intermediate process of a manufacturing method for a display panel provided in some embodiments of the present application;

FIG. 11 is a schematic view of a second intermediate process of a manufacturing method for a display panel provided in some embodiments of the present application; and

FIG. 12 is a schematic view of a display apparatus provided in some embodiments of the present application.

### LIST OF REFERENCE SIGNS

Display panel 100; display apparatus 200; substrate 10;
Inorganic encapsulation layer 20; first inorganic encapsulation layer 201; second inorganic encapsulation layer 202; third inorganic encapsulation layer 203;
Repair encapsulation layer 30; first repair encapsulation layer 301; second repair encapsulation layer 302; third repair encapsulation layer 303;
Organic encapsulation layer 40; first organic encapsulation layer 401; second organic encapsulation layer 402;
Depression 20; first surface 30a; first sub-portion 20b; first thickness d1; second thickness d2; third thickness d3; touch layer 50.

### Detailed Description

For the convenience of understanding the present application, a more comprehensive description of the present application is provided below with reference to the relevant accompanying drawings. Preferred embodiments of the present application are shown in the accompanying drawings. However, the present application can be implemented in many different forms, and is not limited to the embodiments described herein. On the contrary, these embodiments are provided for a more thorough and comprehensive understanding of the disclosure of the present application.

Unless otherwise defined, all technological and scientific terms used herein have the same meanings as commonly understood by those of ordinary skill in the technical field of the present application. The terms used in the description of the present application are only for the purpose of describing specific embodiments, but are not intended to limit the present application. The term “and/or” used herein includes any and all combinations of one or more relevant listed items.

When describing positional relationships, unless otherwise specified, when one element such as a layer, film, or substrate is referred to as “on” the other element, the element may be directly on the other element or there may be an intermediate element between them. Further, when one layer is referred to as “below” the other layer, the layer may be directly below or there may be one or more intermediate elements between them. It can also be understood that when one layer is referred to as “between” two layers, the layer may be the only layer between the two layers, or there may be one or more intermediate elements between them.

When the terms “include”, “have”, and “comprise” described herein are used, another component may be added unless explicit limiting terms such as “only” and “composed of” are used. Unless mentioned to the contrary, the terms in singular forms may include plural forms and cannot be understood as having one.

It should be understood that although the terms “first”, “second”, etc. may be used herein to describe various elements, these elements should not be limited by these terms. These terms are only used to distinguish one element from another. For example, without departing from the scope of the present application, the first element may be referred to as the second element, and similarly, the second element may be referred to as the first element.

It should also be understood that when an element is interpreted, although not explicitly described, the element is interpreted as including an error range, which should be within a specific acceptable deviation range determined by those skilled in the art. For example, “about”, “approximately”, or “essentially” may mean within one or more standard deviations, which are not limited here.

In the description, the phrase “planar distribution view” refers to an accompanying drawing when viewing a target portion from above, and the phrase “cross-sectional view” refers to an accompanying drawing when viewing a cross-section taken by vertically cutting a target portion from a side.

In addition, the accompanying drawings are not drawn to a 1:1 scale, and the relative dimensions of each element are only shown as an example in the accompanying drawings, not necessarily drawn to true scale.

As mentioned in the background, there is the problem of reliability degradation caused by defects in encapsulation layers of the display panel in related arts. The inventor found the cause for the above problem is that the encapsulation structure of the display panel in related arts can block water and oxygen to a certain extent, but still has certain disadvantages, for example, there are defects on the surface of or inside the inorganic encapsulation layer, and the water and oxygen blocking capability is limited to a certain extent, resulting in reliability degradation of the display panel, so that the existing encapsulation structure cannot meet commercial requirements, especially cannot meet higher encapsulation performance requirements of medium-and large-sized display panels.

In view of the above technical problem, the inventor found by research that disposing a repair encapsulation layer on the side of the inorganic encapsulation layer away from the substrate can improve the encapsulation performance and reliability of the display panel. On this basis, the inventor further developed embodiments of the present application. Specifically, the display panel provided in embodiments of the present application includes a substrate, at least one inorganic encapsulation layer, and at least one repair encapsulation layer, where the inorganic encapsulation layer is made of an inorganic material and disposed on one side of the substrate; the repair encapsulation layer is disposed on the side of the at least one inorganic encapsulation layer away from the substrate, and the repair encapsulation layer is in contact with the inorganic encapsulation layer adjacently disposed on a side of the repair encapsulation layer close to the substrate; and materials of the repair encapsulation layers include an inorganic material and an organic material. By adopting the above technical solution, the repair encapsulation layer is disposed on the side of the inorganic encapsulation layer away from the substrate, the repair encapsulation layer is in contact with the inorganic encapsulation layer adjacently disposed on a side of the repair encapsulation layer close to the substrate, and the materials of the repair encapsulation layer include an inorganic material and an organic material, where the material in the repair encapsulation layer can fill the defects such as depressions on the surface of the inorganic encapsulation layer, and the material in the repair encapsulation layer can infiltrate into the defects such as voids inside the inorganic encapsulation layer to repair the defects in the inorganic encapsulation layer and fill and block water and oxygen diffusion paths, thereby improving the water and oxygen blocking capability of the display panel and improving the reliability of the display panel.

The above is the core idea of the present application. The following clearly and completely describes embodiments of the present application with reference to the accompanying drawings in embodiments of the present application. Based on embodiments in the present application, all other embodiments obtained by those of ordinary skill in the art without creative efforts fall within the scope of protection of the present application.

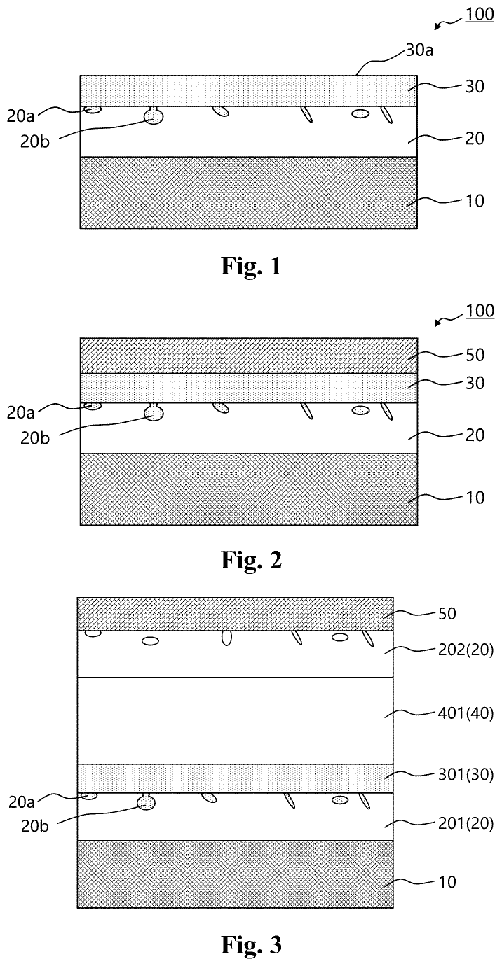

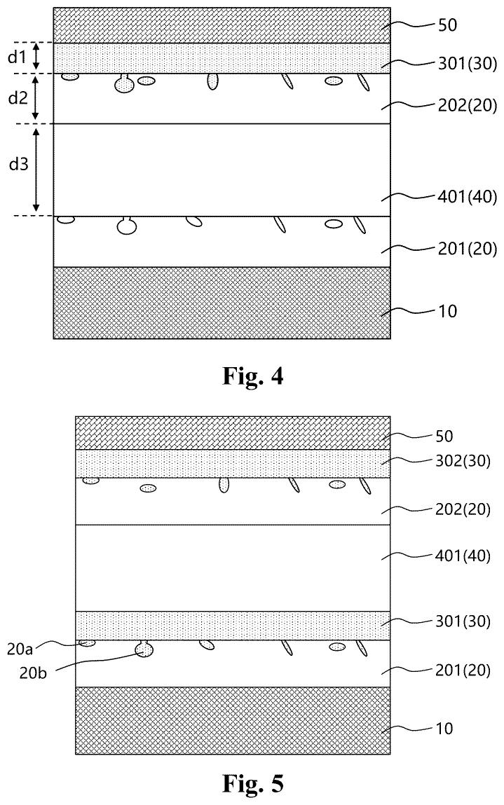

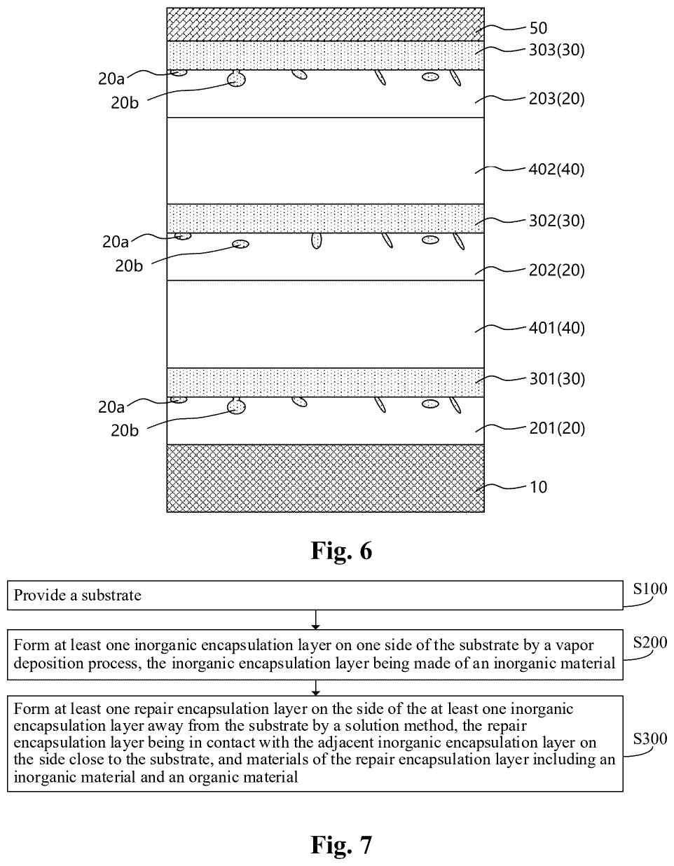

Referring to FIG. 1 to FIG. 6, where FIG. 1 is a schematic view of a first cross-sectional structure of a display panel provided in some embodiments of the present application; FIG. 2 is a schematic view of a second cross-sectional structure of a display panel provided in some embodiments of the present application; FIG. 3 is a schematic view of a third cross-sectional structure of a display panel provided in some embodiments of the present application; FIG. 4 is a schematic view of a fourth cross-sectional structure of a display panel provided in some embodiments of the present application; FIG. 5 is a schematic view of a fifth cross-sectional structure of a display panel provided in some embodiments of the present application; and FIG. 6 is a schematic view of a sixth cross-sectional structure of a display panel provided in some embodiments of the present application.

In a first aspect, with reference to FIG. 1 to FIG. 6, the present application provides a display panel 100. The display panel 100 includes a substrate 10, at least one inorganic encapsulation layer 20, and at least one repair encapsulation layer 30; the inorganic encapsulation layer 20 is made of an inorganic material, and the inorganic encapsulation layer 20 is disposed on one side of the substrate 10; the repair encapsulation layer 30 is disposed on the side of the at least one inorganic encapsulation layer 20 away from the substrate 10, and the repair encapsulation layer 30 is in contact with the inorganic encapsulation layer 20 adjacently disposed on a side of the repair encapsulation layer 20 close to the substrate 10; and materials of the repair encapsulation layer 30 includes an inorganic material and an organic material.

For example, the substrate 10 may be a glass substrate or a flexible substrate. For example, the material of the substrate 10 includes polyimide, which is not limited here.

For example, the display panel 100 may include an array composite film layer and a plurality of light-emitting devices located between the substrate 10 and an encapsulation structure/layer. The display panel 100 may include an array composite film layer located between the substrate 10 and the inorganic encapsulation layer 20 closest to the substrate 10. The array composite film layer may include a plurality of driving circuits and a plurality of driving traces.

For example, in some embodiments, as shown in FIG. 1 and FIG. 2, the display panel 100 may include one inorganic encapsulation layer 20 and one repair encapsulation layer 30, the repair encapsulation layer 30 is disposed on the side of the inorganic encapsulation layer 20 away from the substrate 10, and the repair encapsulation layer 30 is in contact with the inorganic encapsulation layer 20.

For example, in other embodiments, as shown in FIG. 3 to FIG. 6, the display panel 100 may include at least one inorganic encapsulation layer 20 and at least one repair encapsulation layer 30, that is, the display panel 100 may include two or more inorganic encapsulation layers 20, and the display panel 100 may include two or more repair encapsulation layers 30. For example, the display panel 100 may further include other film layers, such as at least one organic encapsulation layer 40.

For example, in some embodiments, the inorganic encapsulation layer 20 may be manufactured using a chemical vapor deposition (CVD) process. The inorganic encapsulation layer 20 has good capability of blocking water vapor and oxygen. However, the surface of the inorganic encapsulation layer is prone to defects such as depressions, and the interior of the inorganic encapsulation layer is prone to defects such as voids. These defects may form channels for the water vapor and oxygen to invade the display panel, thereby reducing the water and oxygen blocking capability of the encapsulation layer/structure and reducing the reliability of the display panel.

For example, in other embodiments, the inorganic encapsulation layer 20 may be formed using methods other than a solution method. For example, the inorganic encapsulation layer 20 is formed by a sputtering process.

For example, the material of the inorganic encapsulation layer 20 may include at least one of silicon nitride, silicon oxide, aluminum oxide, titanium oxide, zinc oxide, tin oxide, or zinc tin oxide.

For example, in some embodiments, the materials of the repair encapsulation layer 30 include an inorganic material and an organic material. The repair encapsulation layer 30 may be manufactured using a solution process, such as printing, spin coating, printing, or spray coating. In the manufacturing process of the repair encapsulation layer 30, the material of the repair encapsulation layer 30 can fill the defects such as depressions on the surface of the inorganic encapsulation layer, and the material of the repair encapsulation layer 30 can infiltrate into and fill the defects such as voids inside the inorganic encapsulation layer, thereby repairing the defects of the inorganic encapsulation layer 20, blocking diffusion paths of water and oxygen, and improving the reliability of the display panel.

To sum up, in embodiments of the present application, the repair encapsulation layer is disposed on the side of the inorganic encapsulation layer away from the substrate, the repair encapsulation layer 30 is in contact with the inorganic encapsulation layer 20 adjacently disposed on a side of the repair encapsulation layer 20 close to the substrate 10, and the materials of the repair encapsulation layer 30 include an inorganic material and an organic material, where in the manufacturing process of the repair encapsulation layer 30, the material of the repair encapsulation layer 30 can fill the defects such as depressions on the surface of the inorganic encapsulation layer, and the material of the repair encapsulation layer 30 can infiltrate into and fill the defects such as voids inside the inorganic encapsulation layer 20, thereby repairing the defects of the inorganic encapsulation layer 20, blocking the diffusion paths of water and oxygen, and improving the encapsulation performance and reliability of the display panel. Meanwhile, in the forming process of the repair encapsulation layer 30 (curing process), when the repair encapsulation layer 30 repairs the defects of the inorganic encapsulation layer 20, the material in the repair encapsulation layer 30 can combine with the atoms of the material in the inorganic encapsulation layer 20, to further fill the defects and better block water vapor paths, thereby better improving the encapsulation performance and reliability of the display panel.

In some embodiments, as shown in FIG. 1, the at least one inorganic encapsulation layer 20 includes at least one depression 20a, the at least one repair encapsulation layer 30 fills the depression 20a, and the surface of the repair encapsulation layer 30 away from the depression 20a is a flat surface.

For example, as shown in FIG. 1, the surface of the inorganic encapsulation layer 20 is prone to defects such as a depression 20a, the repair encapsulation layer 30 fills the depression 20a, and the surface (the first surface 30a) of the repair encapsulation layer 30 away from the depression 20a is maintained as a flat surface. The first surface 30a as shown in FIG. 1 is a flat surface. The surface of the repair encapsulation layer 30 away from the substrate 10 is less prone to defects. The material of the repair encapsulation layer 30 can fill the defects such as the depression 20a on the surface of the inorganic encapsulation layer, thereby repairing the depression 20a of the inorganic encapsulation layer 20, blocking the diffusion paths of water and oxygen, and improving the reliability of the display panel.

In some embodiments, as shown in FIG. 1, the display panel 100 further includes at least one first sub-portion 20b, at least a portion of the first sub-portion 20b is located inside the inorganic encapsulation layer 20, and the material of the first sub-portion 20b is the same as that of the repair encapsulation layer 30.

For example, a portion of the first sub-portion 20b is located inside the inorganic encapsulation layer 20, or all of the first sub-portion 20b is located inside the inorganic encapsulation layer 20, the repair encapsulation layer 30 infiltrates into and fills the defects such as voids inside the inorganic encapsulation layer to form the first sub-portion 20b, and the material of the first sub-portion 20b is the same as that of the repair encapsulation layer 30.

For example, as shown in FIG. 1, the interior of the inorganic encapsulation layer 20 is prone to defects such as voids, the material of the repair encapsulation layer 30 can infiltrate into and fill the defects such as voids inside the inorganic encapsulation layer 20 to form the first sub-portion 20b, and the material of the first sub-portion 20b is the same as that of the repair encapsulation layer 30, thereby repairing the defects in the inorganic encapsulation layer 20, blocking the diffusion paths of water and oxygen, and improving the reliability of the display panel.

In some embodiments, the inorganic material in the repair encapsulation layer 30 includes at least one of silicon nitride, silicon oxide, aluminum oxide, titanium oxide, zinc oxide, tin oxide, or zinc tin oxide.

For example, silicon nitride, silicon oxide, aluminum oxide, titanium oxide, zinc oxide, tin oxide, and zinc tin oxide have excellent water and oxygen blocking capabilities, which can improve the water and oxygen blocking capability for repaired places (the repaired depression 20a and first sub-portion 20b) in the inorganic encapsulation layer 20 and enable the repair encapsulation layer 30 to have certain water and oxygen blocking capability.

In some embodiments, the organic material in the repair encapsulation layer 30 includes at least one of pure hydrocarbons, hexamethylcyclotrisilazane, cyclopentasiloxane, dibutyl ether, toluene, or xylene.

For example, the repair encapsulation layer 30 is formed using a solution method. The solution used in the solution method includes at least one of a precursor solution of perhydropolysilazane, a precursor solution of aluminum oxide, a precursor solution of titanium oxide, a precursor solution of zinc oxide, a precursor solution of tin oxide, and a precursor solution of zinc tin oxide. After removal of a solvent and/or curing, the organic material in the repair encapsulation layer 30 includes at least one of pure hydrocarbons, hexamethylcyclotrisilazane, cyclopentasiloxane, dibutyl ether, toluene, or xylene.

For example, when the solution used in the solution method is the precursor solution of perhydropolysilazane, the precursor solution includes at least one of a pure hydrocarbon solvent, hexamethylcyclotrisilazane, cyclopentasiloxane, dibutyl ether, toluene, and xylene.

For example, when the solution used in the solution method is the precursor solution of aluminum oxide, the precursor solution includes a polymer aluminium sulfate complex.

For example, when the solution used in the solution method is the precursor solution of zinc tin oxide, the precursor solution includes at least one of zinc acetate dihydrate, anhydrous zinc acetate, and tin 2-ethylhexanoate.

In some embodiments, the inorganic material in the at least one repair encapsulation layer 30 is the same as the material of the at least one inorganic encapsulation layer 20; and for the repair encapsulation layer 30 and the inorganic encapsulation layer 20 of the same inorganic material, a refractive index of the repair encapsulation layer 30 is less than that of the inorganic encapsulation layer 20.

For example, the inorganic material in the repair encapsulation layer 30 is the same as the material of the inorganic encapsulation layer 20, and the repair encapsulation layer 30 is in contact with the inorganic encapsulation layer 20, which can improve the adhesion or film bonding strength between the repair encapsulation layer 30 and the inorganic encapsulation layer 20 to prevent peeling between film layers.

For example, in some embodiments, the inorganic encapsulation layer 20 may be manufactured using a chemical vapor deposition (CVD) process, and the repair encapsulation layer 30 may be manufactured using a solution process. Compared to the repair encapsulation layer 30, the inorganic material in the inorganic encapsulation layer 20 is denser. When the inorganic material in the repair encapsulation layer 30 is the same as the material of the inorganic encapsulation layer 20, a refractive index of the repair encapsulation layer 30 is less than that of the inorganic encapsulation layer 20.

In some embodiments, the refractive index of the repair encapsulation layer 30 is 1.6 to 2. In some embodiments, the refractive index of the inorganic encapsulation layer 20 is 1.5 to 1.9.

For example, the refractive index of the repair encapsulation layer 30 is 1.6 to 2. For example, the refractive index of the repair encapsulation layer 30 is any one of 1.6, 1.7, 1.8, 1.9, and 2.

For example, the refractive index of the inorganic encapsulation layer 20 is 1.5 to 1.9. For example, the refractive index of the inorganic encapsulation layer 20 is any one of 1.5, 1.6, 1.7, 1.8, and 1.9.

For example, the refractive index difference between the inorganic encapsulation layer 20 and the organic encapsulation layer 40 is large, and light emitted by the display panel 100 is prone to be reflected at an interface between the inorganic encapsulation layer 20 and the organic encapsulation layer 40, resulting in a decrease in light output efficiency. Therefore, the repair encapsulation layer 30 having an appropriate refractive index is disposed, and the repair encapsulation layer 30 plays a role in refractive index transition between the inorganic encapsulation layer 20 and the organic encapsulation layer 40 (for example, the refractive index of the repair encapsulation layer 30 is between those of the inorganic encapsulation layer 20 and the organic encapsulation layer 40; for example, the refractive index of the repair encapsulation layer 30 is less than that of the inorganic encapsulation layer 20, and the refractive index of the repair encapsulation layer 30 is greater than that of the organic encapsulation layer), so the repair encapsulation layer 30 can further reduce the refractive index gradient difference between the inorganic encapsulation layer 20 and the organic encapsulation layer 40, thereby improving the light output efficiency of the display panel.

In some embodiments, a thickness of the repair encapsulation layer 30 is less than that of the inorganic encapsulation layer 20.

For example, in some embodiments, the inorganic encapsulation layer 20 has good water and oxygen blocking capability, and the repair encapsulation layer 30 functions to repair the defects in the inorganic encapsulation layer 20 to block water and oxygen invasion channels formed by the defects in the inorganic encapsulation layer 20. Therefore, if the thickness of the repair encapsulation layer 30 is less than that of the inorganic encapsulation layer 20, the inorganic encapsulation layer 20 can be repaired while excessive thickness of the encapsulation layer/structure can be prevented.

For example, as shown in FIG. 4, the thickness of the repair encapsulation layer 30 is a first thickness d1, the thickness of the inorganic encapsulation layer 20 is a second thickness d2, and the first thickness d1 is less than the second thickness d2.

In some embodiments, a ratio of the thickness of the repair encapsulation layer 30 to the thickness of the inorganic encapsulation layer 20 is 0.1 to 0.2.

For example, the ratio of the first thickness d1 to the second thickness d2 is in a range of 0.1 to 0.2. For example, the ratio of the first thickness d1 to the second thickness d2 may be any one of 0.1, 0.12, 0.14, 0.15, 0.17, 0.19, and 0.2.

For example, by setting an appropriate ratio of the first thickness d1 to the second thickness d2, the repair encapsulation layer 30 can repair the inorganic encapsulation layer 20 and prevent excessive thickness of the encapsulation layer/structure.

In some embodiments, the thickness of the repair encapsulation layer 30 is 10 nanometers to 300 nanometers.

For example, the first thickness d1 may be any one of 10 nanometers, 50 nanometers, 100 nanometers, 150 nanometers, 200 nanometers, 250 nanometers, and 300 nanometers.

For example, after verification by the inventor, it was found that when the thickness of the repair encapsulation layer 30 is 10 nanometers to 300 nanometers, the repair encapsulation layer 30 can repair the inorganic encapsulation layer 20 and prevent excessive thickness of the encapsulation layer/structure.

In some embodiments, the inorganic material in the at least one repair encapsulation layer 30 is the same as the material of the inorganic encapsulation layer 20 located on the side of the repair encapsulation layer 30 close to the substrate 10 and adjacent to the repair encapsulation layer 30.

For example, the display panel 100 may include one or more repair encapsulation layers 30, the display panel 100 may include one or more inorganic encapsulation layers 20, at least one of the repair encapsulation layers 30 is in contact with the inorganic encapsulation layer 20 that is located on the side of the repair encapsulation layer 30 close to the substrate 10, and the repair encapsulation layer 30 and the inorganic encapsulation layer 20 include the same inorganic material. On the one hand, after the inorganic material in the repair encapsulation layer 30 fills or infiltrate in the interior of the inorganic encapsulation layer 20 via the organic material, a denser repair structure can be formed to enhance the water and oxygen blocking capability. On the other hand, the adhesion and film bonding strength between the repair encapsulation layer 30 and the inorganic encapsulation layer 20 can be improved to prevent peeling between film layers.

In some embodiments, as shown in FIG. 3 and FIG. 4, the display panel 100 includes a plurality of inorganic encapsulation layers 20, the plurality of inorganic encapsulation layers 20 include a first inorganic encapsulation layer 201 and a second inorganic encapsulation layer 202, and the display panel 100 further includes a first organic encapsulation layer 401; the first organic encapsulation layer 401 is disposed on the side of the first inorganic encapsulation layer 201 away from the substrate 10, and the second inorganic encapsulation layer 202 is disposed on the side of the first organic encapsulation layer 401 away from the substrate 10; at least one repair encapsulation layer 30 includes a first repair encapsulation layer 301, and the first repair encapsulation layer 301 is disposed between the first inorganic encapsulation layer 201 and the first organic encapsulation layer 401 or on the side of the second inorganic encapsulation layer 202 away from the substrate 10.

For example, the organic encapsulation layer 40 may include acrylic or epoxy series polymers, and may be prepared by coating, spin coating, or the like, which is described only as an example and is not limited.

For example, in some embodiments, as shown in FIG. 3, the first repair encapsulation layer 301 is disposed between the first inorganic encapsulation layer 201 and the first organic encapsulation layer 401; the first inorganic encapsulation layer 201, the first repair encapsulation layer 301, the first organic encapsulation layer 401, and the second inorganic encapsulation layer 202 are sequentially stacked on one side of the substrate 10, the first repair encapsulation layer 301 is in contact with the first inorganic encapsulation layer 201, and the first repair encapsulation layer 301 is used for repairing defects in the first inorganic encapsulation layer 201.

For example, in some embodiments, as shown in FIG. 4, the first repair encapsulation layer 301 is disposed on the side of the second inorganic encapsulation layer 202 away from the substrate 10; the first inorganic encapsulation layer 201, the first organic encapsulation layer 401, the second inorganic encapsulation layer 202, and the first repair encapsulation layer 301 are sequentially stacked on one side of the substrate 10, the first repair encapsulation layer 301 is in contact with the second inorganic encapsulation layer 202, and the first repair encapsulation layer 301 is used for repairing defects in the second inorganic encapsulation layer 202.

For example, in embodiments of FIG. 3 and FIG. 4, the display panel 100 includes inorganic encapsulation layers 20 and organic encapsulation layers 40 disposed alternately, and the first repair encapsulation layer 301 repairs defects in the first inorganic encapsulation layer 201 or the second inorganic encapsulation layer 202, which can enhance water and oxygen blocking capability, enhance encapsulation performance, and improve the reliability of the display panel.

In some embodiments, the thickness of the repair encapsulation layer 30 is less than that of the inorganic encapsulation layer 20 or/and that of the first organic encapsulation layer 401.

For example, as shown in FIG. 4, the thickness of the first organic encapsulation layer 401 or the organic encapsulation layer 40 is a third thickness d3.

For example, in some embodiments, the thickness of the repair encapsulation layer 30 is less than that of the inorganic encapsulation layer 20, that is, the first thickness d1 is less than the second thickness d2.

For example, in some embodiments, the thickness of the repair encapsulation layer 30 is less than that of the organic encapsulation layer 40, that is, the first thickness d1 is less than the third thickness d3.

For example, in some embodiments, the thickness of the repair encapsulation layer 30 is less than that of the inorganic encapsulation layer 20, and the thickness of the inorganic encapsulation layer 20 is less than that of the organic encapsulation layer 40, that is, the first thickness d1 is less than the second thickness d2, and the second thickness d2 is less than the third thickness d3.

For example, compared to the inorganic encapsulation layer 20 or/and the organic encapsulation layer 40, when the thickness of the repair encapsulation layer 30 is an appropriate value, on the one hand, the adhesion between the repair encapsulation layer 30 and the adjacent film layer can be enhanced; for example, the inorganic material in the repair encapsulation layer 30 includes a silicon element, which facilitates the formation of hydrogen bonds between Si—H bonds and —OH bonds in the organic encapsulation layer 40, thereby enhancing the adhesion. On the other hand, the refractive index difference between the inorganic encapsulation layer 20 and the organic encapsulation layer 40 is large, and the light emitted by the display panel 100 is prone to be reflected at the interface between the inorganic encapsulation layer 20 and the organic encapsulation layer 40, resulting in a decrease in light output efficiency. Therefore, the repair encapsulation layer 30 plays a role in refractive index transition between the inorganic encapsulation layer 20 and the organic encapsulation layer 40 (for example, the refractive index of the repair encapsulation layer 30 is between those of the inorganic encapsulation layer 20 and the organic encapsulation layer 40; for example, the refractive index of the repair encapsulation layer 30 is less than that of the inorganic encapsulation layer 20, and the refractive index of the repair encapsulation layer 30 is greater than that of the organic encapsulation layer), and the repair encapsulation layer 30 can further reduce the refractive index gradient difference between the inorganic encapsulation layer 20 and the organic encapsulation layer 40, thereby improving the light output efficiency of the display panel.

In some embodiments, as shown in FIG. 5, the display panel 100 includes a plurality of repair encapsulation layers 30, the plurality of repair encapsulation layers 30 include a first repair encapsulation layer 301 and a second repair encapsulation layer 302; one of the first repair encapsulation layer 301 and the second repair encapsulation layer 302 is disposed between the first inorganic encapsulation layer 201 and the first organic encapsulation layer 401, and the other of the first repair encapsulation layer 301 and the second repair encapsulation layer 302 is disposed on the side of the second inorganic encapsulation layer 202 away from the substrate 10.

For example, in some embodiments, as shown in FIG. 5, the first repair encapsulation layer 301 is disposed on the side of the first inorganic encapsulation layer 201 away from the substrate 10, and the second repair encapsulation layer 302 is disposed on the side of the second inorganic encapsulation layer 202 away from the substrate 10; the first inorganic encapsulation layer 201, the first repair encapsulation layer 301, the first organic encapsulation layer 401, the second inorganic encapsulation layer 202, and the second repair encapsulation layer 302 are sequentially stacked on one side of the substrate 10; the first repair encapsulation layer 301 is in contact with the first inorganic encapsulation layer 201, the first repair encapsulation layer 301 is used for repairing defects in the first inorganic encapsulation layer 201, the second repair encapsulation layer 302 is in contact with the second inorganic encapsulation layer 202, and the second repair encapsulation layer 302 is used for repairing defects in the second inorganic encapsulation layer 202.

For example, in embodiments of FIG. 5, the display panel 100 includes inorganic encapsulation layers 20 and organic encapsulation layers 40 disposed alternately, and a plurality of repair encapsulation layers 30 are disposed to repair the plurality of inorganic encapsulation layers 20 respectively, which can improve the water and oxygen blocking capability of the plurality of inorganic encapsulation layers 20, thereby better improving the encapsulation performance and reliability of the display panel.

For example, as shown in FIG. 6, the plurality of inorganic encapsulation layers 20 include a first inorganic encapsulation layer 201, a second inorganic encapsulation layer 202, and a third inorganic encapsulation layer 203; the plurality of repair encapsulation layers 30 include a first repair encapsulation layer 301, a second repair encapsulation layer 302, and a third repair encapsulation layer 303; and the plurality of organic encapsulation layers 40 include a first organic encapsulation layer 401 and a second organic encapsulation layer 402. The first inorganic encapsulation layer 201, the first repair encapsulation layer 301, the first organic encapsulation layer 401, the second inorganic encapsulation layer 202, the second repair encapsulation layer 302, the second organic encapsulation layer 402, the third inorganic encapsulation layer 203, and the third repair encapsulation layer 303 are sequentially stacked on one side of substrate 10.

For example, in some embodiments, as shown in FIG. 2 to FIG. 6, the display panel 100 may further include other film layers or structures. For example, the display panel 100 may further include a touch layer 50 or a polarizer located on the side of the encapsulation layer away from the substrate 10.

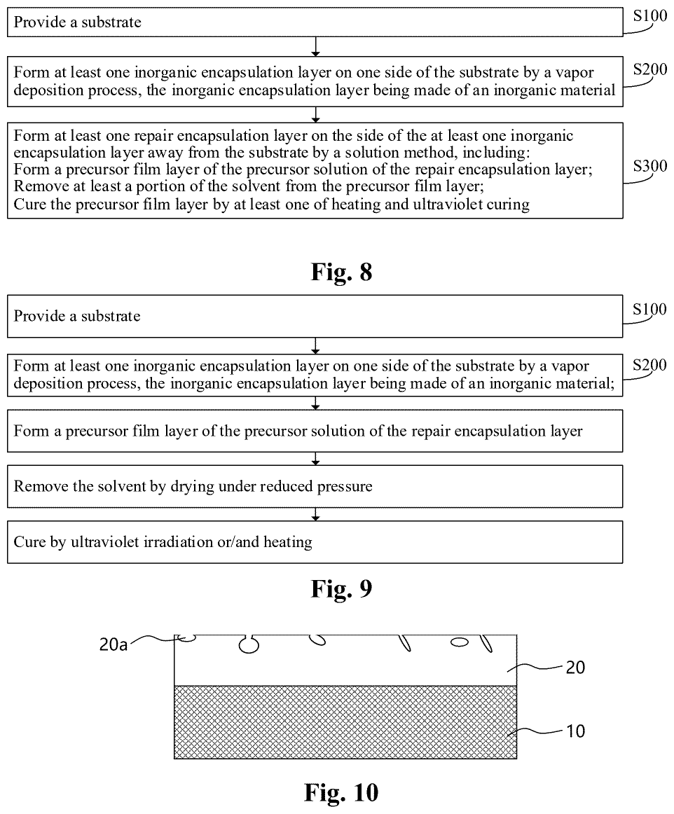

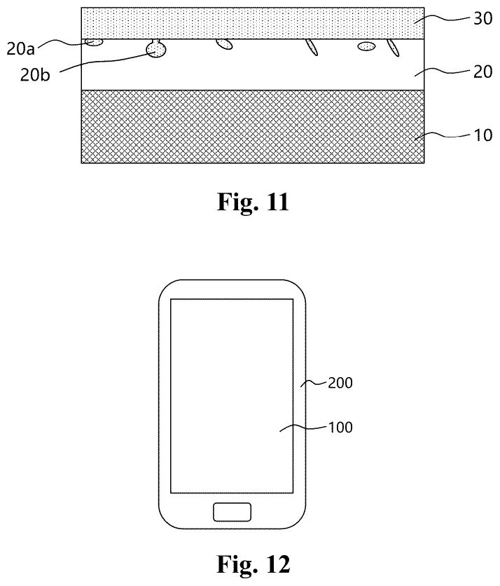

Referring to FIG. 7 to FIG. 11, FIG. 7 is a schematic view of first process steps of a manufacturing method for a display panel provided in some embodiments of the present application; FIG. 8 is a schematic view of second process steps of a manufacturing method for a display panel provided in some embodiments of the present application; FIG. 9 is a schematic view of third process steps of a manufacturing method for a display panel provided in some embodiments of the present application; FIG. 10 is a schematic view of a first intermediate process of a manufacturing method for a display panel provided in some embodiments of the present application; and FIG. 11 is a schematic view of a second intermediate process of a manufacturing method for a display panel provided in some embodiments of the present application.

In a second aspect, the present application further provides a manufacturing method for a display panel, and any of the above display panels 100 can be manufactured using the manufacturing method. The manufacturing method for the display panel includes steps S100, S200, and S300.

Step S100: Provide a substrate 10.

Step S200: Form at least one inorganic encapsulation layer 20 on one side of the substrate 10 by a vapor deposition process, the inorganic encapsulation layer 20 being made of an inorganic material.

For example, the inorganic encapsulation layer 20 formed by the vapor deposition process has good water and oxygen blocking capability.

For example, the material of the inorganic encapsulation layer 20 may include at least one of silicon nitride, silicon oxide, aluminum oxide, titanium oxide, zinc oxide, tin oxide, or zinc tin oxide.

For example, as shown in FIG. 10, the surface of the inorganic encapsulation layer 20 is prone to defects such as depressions 20a, and the interior of the inorganic encapsulation layer 20 is prone to defects such as voids. These defects may form channels for water vapor and oxygen to invade the display panel, thereby reducing the water and oxygen blocking capability of the encapsulation layer/structure and reducing the reliability of the display panel.

Step S300: Form at least one repair encapsulation layer 30 on the side of the at least one inorganic encapsulation layer 20 away from the substrate 10 by a solution method, the repair encapsulation layer 30 being in contact with the inorganic encapsulation layer 20 adjacently disposed on a side of the repair encapsulation layer 20 close to the substrate 10, and materials of the repair encapsulation layer 30 including an inorganic material and an organic material.

For example, as shown in FIG. 11, when a precursor film layer of the repair encapsulation layer 30 is formed by the solution method, the precursor film layer includes an inorganic material and an organic material, the organic material can drive the inorganic material to fill in the defects such as depressions 20a, and the organic material can drive the inorganic material to infiltrate into the defects such as voids. Therefore, the repair encapsulation layer 30 formed by the solution method can fill the defects such as depressions on the surface of the inorganic encapsulation layer, and the material in the repair encapsulation layer can infiltrate into the defects such as voids inside the inorganic encapsulation layer to repair the defects in the inorganic encapsulation layer and fill and block water and oxygen diffusion paths, thereby improving the water and oxygen blocking capability of the display panel and improving the reliability of the display panel.

In the manufacturing method for the display panel in embodiments of the present application, the repair encapsulation layer 30 is disposed on the side of the inorganic encapsulation layer 20 away from the substrate, the repair encapsulation layer 30 is in contact with the inorganic encapsulation layer 20 adjacently disposed on a side of the repair encapsulation layer 20 close to the substrate 10, and the materials of the repair encapsulation layer 30 include an inorganic material and an organic material, where in the manufacturing process of the repair encapsulation layer 30, the repair encapsulation layer 30 is formed by a solution method, the material of the repair encapsulation layer 30 can fill the defects such as depressions on the surface of the inorganic encapsulation layer, and the material of the repair encapsulation layer 30 can infiltrate into and fill the defects such as voids inside the inorganic encapsulation layer 20, thereby repairing the defects of the inorganic encapsulation layer 20, blocking the diffusion paths of water and oxygen, and improving the encapsulation performance and reliability of the display panel. Meanwhile, in the forming process of the repair encapsulation layer 30 (curing process), when the repair encapsulation layer 30 repairs the defects of the inorganic encapsulation layer 20, the material in the repair encapsulation layer 30 can combine with the atoms of the material in the inorganic encapsulation layer 20, to further fill the defects and better block water vapor paths, thereby better improving the encapsulation performance and reliability of the display panel.

In some embodiments, the solution used in the solution method includes at least one of a precursor solution of perhydropolysilazane, a precursor solution of aluminum oxide, a precursor solution of titanium oxide, a precursor solution of zinc oxide, a precursor solution of tin oxide, and a precursor solution of zinc tin oxide.

For example, silicon nitride, silicon oxide, aluminum oxide, titanium oxide, zinc oxide, tin oxide, and zinc tin oxide have excellent water and oxygen blocking capabilities, which can improve the water and oxygen blocking capability for repaired places (the repaired depression 20a and first sub-portion 20b) in the inorganic encapsulation layer 20 and enable the repair encapsulation layer 30 to have certain water and oxygen blocking capability.

In some embodiments, when the solution used in the solution method is the precursor solution of perhydropolysilazane, the precursor solution includes at least one of a pure hydrocarbon solvent, hexamethylcyclotrisilazane, cyclopentasiloxane, dibutyl ether, toluene, and xylene;
and/or when the solution used in the solution method is the precursor solution of aluminum oxide, the precursor solution includes a polymer aluminium sulfate complex;
and/or when the solution used in the solution method is the precursor solution of zinc tin oxide, the precursor solution includes at least one of zinc acetate dihydrate, anhydrous zinc acetate, and tin 2-ethylhexanoate.

In some embodiments, as shown in FIG. 8, forming at least one repair encapsulation layer 30 on the side of the at least one inorganic encapsulation layer 20 away from the substrate 10 by a solution method includes: S300a, forming a precursor film layer of the precursor solution of the repair encapsulation layer 30; S300b, removing at least a portion of the solvent from the precursor film layer; and S300c, curing the precursor film layer by at least one of heating and ultraviolet curing.

For example, as shown in FIG. 9, after the precursor film layer of the precursor solution of the repair encapsulation layer 30 is formed, the solvent can be removed by drying under reduced pressure, and then the precursor film layer is cured by ultraviolet radiation or/and heating to form the repair encapsulation layer 30.

For example, in the curing process of the repair encapsulation layer 30, when the repair encapsulation layer 30 repairs the defects of the inorganic encapsulation layer 20, the material in the repair encapsulation layer 30 can combine with the atoms of the material in the inorganic encapsulation layer 20, to further fill the defects and better block water vapor paths, thereby better improving the encapsulation performance and reliability of the display panel.

For example, the irradiation intensity of ultraviolet radiation may be 20 to 85 mW/cm², and the irradiation time is 1 to 10 minutes.

Referring to FIG. 12, FIG. 12 is a schematic view of a display apparatus provided in some embodiments of the present application.

In a third aspect, based on the same concept, the present application further provides a display apparatus 200. The display apparatus 200 includes any of the above display panels 100, or the display apparatus 200 includes a display panel 100 combining several of the above features.

For example, the display apparatus 200 also has the beneficial effects of the display panel 100 in the above embodiments. The similarities can be understood by referring to the explanation of the display panel 100 above, and will not be repeated below.

For example, the display apparatus 200 provided in embodiments of the present application may be a mobile phone shown in FIG. 12, or any electronic product with a display function, including but not limited to the following: televisions, laptops, desktop displays, tablets, digital cameras, smart bracelets, smart glasses, vehicle displays, industrial control devices, medical display screens, touch interaction terminals, etc. Embodiments of the present application do not make special limitations on this.

The technical features of the above embodiments can be combined arbitrarily. For the purpose of simplicity in description, all possible combinations of the technical features in the above embodiments are not described. However, as long as the combinations of these technical features do not have contradictions, they shall fall within the scope of the description.

The above embodiments only describe several embodiments of the present application, and their descriptions are specific and detailed, but cannot therefore be understood as limitations to the patent scope of the present invention. It should be noted that those of ordinary skill in the art can make some variations and improvements without departing from the concept of the present application, and these variations and improvements all fall into the protection scope of the present application. Therefore, the patent protection scope of the present application should be subject to the appended claims.

What is claimed is:

1. A display panel, comprising:
a substrate;
at least one inorganic encapsulation layer, made of an inorganic material and disposed on one side of the substrate; and
at least one repair encapsulation layer, disposed on a side of the at least one inorganic encapsulation layer away from the substrate, and the repair encapsulation layer being in contact with the inorganic encapsulation layer adjacently disposed on a side of the repair encapsulation layer close to the substrate, wherein the repair encapsulation layer comprise an inorganic material and an organic material.

2. The display panel according to claim 1, wherein the at least one inorganic encapsulation layer comprises at least one depression, the at least one repair encapsulation layer fills the depression, and a surface of the repair encapsulation layer away from the depression is a flat surface.

3. The display panel according to claim 1, wherein the display panel further comprises at least one first sub-portion, at least a portion of the first sub-portion is located inside the inorganic encapsulation layer, and a material of the first sub-portion is the same as that of the repair encapsulation layer.

4. The display panel according to claim 1, wherein the inorganic material in the repair encapsulation layer comprises at least one of silicon nitride, silicon oxide, aluminum oxide, titanium oxide, zinc oxide, tin oxide, or zinc tin oxide.

5. The display panel according to claim 1, wherein the organic material in the repair encapsulation layer comprises at least one of pure hydrocarbons, hexamethylcyclotrisilazane, cyclopentasiloxane, dibutyl ether, toluene, or xylene.

6. The display panel according to claim 1, wherein the inorganic material in the at least one repair encapsulation layer is the same as the material of the at least one inorganic encapsulation layer; and
for the repair encapsulation layer and the inorganic encapsulation layer having a same inorganic material, a refractive index of the repair encapsulation layer is less than a refractive index of the inorganic encapsulation layer.

7. The display panel according to claim 1, wherein a refractive index of the repair encapsulation layer is 1.6 to 2; and/or
a refractive index of the inorganic encapsulation layer is 1.5 to 1.9.

8. The display panel according to claim 1, wherein a thickness of the repair encapsulation layer is less than a thickness of the inorganic encapsulation layer.

9. The display panel according to claim 1, wherein a ratio of a thickness of the repair encapsulation layer to a thickness of the inorganic encapsulation layer is 0.1 to 0.2.

10. The display panel according to claim 1, wherein a thickness of the repair encapsulation layer is 10 nanometers to 300 nanometers.

11. The display panel according to claim 1, wherein the inorganic material in the at least one repair encapsulation layer is the same as the inorganic material of the inorganic encapsulation layer adjacently disposed on a side of the repair encapsulation layer close to the substrate.

12. The display panel according to claim 1, wherein the display panel comprises a plurality of the inorganic encapsulation layers, the plurality of the inorganic encapsulation layers comprise a first inorganic encapsulation layer and a second inorganic encapsulation layer, and the display panel further comprises a first organic encapsulation layer;
the first organic encapsulation layer is disposed on a side of the first inorganic encapsulation layer away from the substrate, and the second inorganic encapsulation layer is disposed on a side of the first organic encapsulation layer away from the substrate; and
the at least one repair encapsulation layer comprises a first repair encapsulation layer, and the first repair encapsulation layer is disposed between the first inorganic encapsulation layer and the first organic encapsulation layer or on a side of the second inorganic encapsulation layer away from the substrate.

13. The display panel according to claim 12, wherein a thickness of the repair encapsulation layer is less than a thickness of the inorganic encapsulation layer or/and a thickness of the first organic encapsulation layer.

14. The display panel according to claim 12, wherein the display panel comprises a plurality of the repair encapsulation layers, the plurality of the repair encapsulation layers comprise the first repair encapsulation layer and a second repair encapsulation layer; and
one of the first repair encapsulation layer and the second repair encapsulation layer is disposed between the first inorganic encapsulation layer and the first organic encapsulation layer, and the other of the first repair encapsulation layer and the second repair encapsulation layer is disposed on a side of the second inorganic encapsulation layer away from the substrate.

15. A manufacturing method for a display panel, comprising:
providing a substrate;
forming at least one inorganic encapsulation layer on one side of the substrate by a vapor deposition process, the inorganic encapsulation layer being made of an inorganic material; and
forming at least one repair encapsulation layer on a side of the at least one inorganic encapsulation layer away from the substrate by a solution method, the repair encapsulation layer being in contact with the inorganic encapsulation layer adjacently disposed on a side of the repair encapsulation layer close to the substrate, and the repair encapsulation layer comprising an inorganic material and an organic material.

16. The manufacturing method for the display panel according to claim 15, wherein a solution used in the solution method comprises at least one of a precursor solution of perhydropolysilazane, a precursor solution of aluminum oxide, a precursor solution of titanium oxide, a precursor solution of zinc oxide, a precursor solution of tin oxide, and a precursor solution of zinc tin oxide.

17. The manufacturing method for the display panel according to claim 16, wherein under a condition that the solution used in the solution method is the precursor solution of perhydropolysilazane, the precursor solution comprises at least one of a pure hydrocarbon solvent, hexamethylcyclotrisilazane, cyclopentasiloxane, dibutyl ether, toluene, or xylene;
and/or under a condition that the solution used in the solution method is the precursor solution of aluminum oxide, the precursor solution comprises a polymer aluminium sulfate complex;
and/or under a condition that the solution used in the solution method is the precursor solution of zinc tin oxide, the precursor solution comprises at least one of zinc acetate dihydrate, anhydrous zinc acetate, or tin 2-ethylhexanoate.

18. The manufacturing method for the display panel according to claim 15, wherein the forming at least one repair encapsulation layer on a side of the at least one inorganic encapsulation layer away from the substrate by a solution method comprises:
forming a precursor film layer of a precursor solution of the repair encapsulation layer;
removing at least a portion of a solvent from the precursor film layer; and
curing the precursor film layer by at least one of heating or ultraviolet curing.

19. A display apparatus, comprising a display panel, wherein the display panel comprises:
a substrate;
at least one inorganic encapsulation layer, made of an inorganic material and disposed on one side of the substrate; and
at least one repair encapsulation layer, disposed on a side of the at least one inorganic encapsulation layer away from the substrate, and the repair encapsulation layer being in contact with the inorganic encapsulation layer adjacently disposed on a side of the repair encapsulation layer close to the substrate, wherein the repair encapsulation layer comprise an inorganic material and an organic material.
